(19) United States
(12) Patent Application Publication
(10) Pub. No.: US 2021/0375845 A1
(43) Pub. Date: Dec. 2, 2021

(54) PACKAGE CAVITY FOR ENHANCED DEVICE PERFORMANCE WITH AN INTEGRATED PASSIVE DEVICE

(71) Applicant: QUALCOMM Incorporated, San Diego, CA (US)

(72) Inventors: William Michael STONE, San Diego, CA (US); Ryan LANE, San Diego, CA (US); Ahmer Raza SYED, San Diego, CA (US)

(21) Appl. No.: 16/885,171

(22) Filed: May 27, 2020

(51) Int. Cl. H01L 25/18; H01L 23/498; H01L 23/00; H01L 21/56

(52) U.S. Cl. CPC H01L 25/18; H01L 23/49816; H01L 24/17; H01L 24/16; H01L 2224/81815; H01L 21/563; H01L 24/81; H01L 2224/13147; H01L 2224/16225; H01L 24/13

(57) ABSTRACT

An integrated circuit (IC) package is described. The IC package includes a package die and die interconnects on an active surface of the package die. The IC package also includes an integrated passive device (IPD) coupled to the active surface of the package die, between the plurality of die interconnects. A portion of the IPD extends beyond a Z-height of the die interconnects. The IC package further includes a package substrate coupled to the die interconnects, the package substrate having a cavity to receive the portion of the IPD.

### BACKGROUND

### Field

Aspects of the present disclosure relate to packaging of integrated circuits and, more particularly, to a package cavity for enhanced device performance with an integrated passive device (IPD).

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile applications demand a small form factor, low cost, a tight power budget, and high electrical performance. Package design has evolved to meet these divergent goals for enabling mobile applications that support multimedia enhancements. These mobile applications, however, rely on passive devices to support the noted multimedia enhancements. Unfortunately, passive devices consume valuable chip real estate, which may exceed the small form factor specified for state-of-the-art mobile applications.

### SUMMARY

An integrated circuit (IC) package is described. The IC package includes a package die and die interconnects on an active surface of the package die. The IC package also includes an integrated passive device (IPD) coupled to the active surface of the package die, between the plurality of die interconnects. A portion of the IPD extends beyond a Z-height of the die interconnects. The IC package further includes a package substrate coupled to the die interconnects, the package substrate having a cavity to receive the portion of the IPD.

A method for fabricating an integrated circuit package having a package substrate cavity for an integrated passive device (IPD) is described. The method includes forming die interconnects on an active surface of a package die. The method also includes mounting the IPD on the active surface of the package die, in which the IPD is between the die interconnects. The method further includes forming the package substrate cavity in a package substrate to receive a portion of the IPD extending beyond a Z-height of the plurality of die interconnects. The method also includes attaching the package substrate to the package die through the plurality of die interconnects.

An integrated circuit (IC) package is described. The IC package includes a package die and die interconnects on an active surface of the package die. The IC package also includes an integrated passive device (IPD) coupled to the active surface of the package die, between the plurality of die interconnects. A portion of the IPD extends beyond a Z-height of the die interconnects. The IC package further includes a package substrate coupled to the die interconnects, the package substrate having a cavity to receive the portion of the IPD. The IC package also includes means for filling between the IPD and the cavity of the package substrate and between the die interconnects and the IPD.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-a-chip (SoC), including a package substrate cavity for an integrated passive device (IPD), in accordance with certain aspects of the present disclosure.

FIG. 2 shows a cross-sectional view of a stacked integrated circuit (IC) package, including the system-on-a-chip (SoC) of FIG. 1.

FIG. 3 shows a cross-sectional view illustrating the stacked integrated circuit (IC) package of FIG. 2, incorporated into a wireless device, according to one aspect of the present disclosure.

FIG. 4 is a cross-section of an integrated circuit (IC) package having a package substrate cavity for an integrated passive device (IPD), according to aspects of the present disclosure.

FIGS. 5A-5D are cross-section diagrams illustrating a process of fabricating the IC package having the package substrate cavity for the integrated passive device (IPD) of FIG. 4, according to aspects of the present disclosure.

FIG. 6 is a process flow diagram illustrating a method for fabricating an integrated circuit (IC) package having a package substrate cavity for an integrated passive device (IPD), according to an aspect of the present disclosure.

FIG. 7 is a block diagram showing an exemplary wireless communications system in which a configuration of the disclosure may be advantageously employed.

FIG. 8 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

A system hierarchy includes interconnection of active devices at a lowest system level all the way up to system level interconnections at a highest level. In particular, electrical connections exist at each of the levels of the system hierarchy to connect different devices together on an integrated circuit. As integrated circuits become more complex, however, more interconnect layers are used to provide the electrical connections between the devices. More recently, the number of interconnect levels for circuitry has substantially increased due to the large number of devices that are now interconnected in a modern electronic device.

State-of-the-art mobile applications demand a small form factor, low cost, a tight power budget, and high electrical performance. Package design has evolved to meet these divergent goals for enabling mobile applications that support various technology innovations, which are driving the demand for massive processing speed of an application processor. These technology innovations include, for example, autonomous driving, industry Internet-of-things (IOT), remote medical operations/resource sharing, and infotainment/gaming/education. Other technology innovations include interactive collaborations with artificial intelligence (AI) and virtual reality (VR)/artificial reality (AR)/mixed reality (MR)/extended reality (XR) devices.

In addition, media applications are also driving the demand for massive processing speed of mobile application processors. In particular, live high definition (HD) video (e.g., 4K/8K) and high frequency voice over Internet protocol (HF VoIP) audio content transmission for mixed reality (MR) and extended reality (XR) specify both downlink and uplink speeds much higher than ten gigabytes per second (10 Gbps). These massive data transmission rates may be realized with millimeter wave (mmWave) communications that can offer increased bandwidth. Successful operation of a mobile application processor, however, relies on passive devices to support the noted multimedia enhancements. Unfortunately, passive devices consume valuable chip real estate, which may exceed the small form factor specified for state-of-the-art mobile applications.

Various aspects of the present disclosure provide a package substrate cavity for an integrated passive device (IPD). The process flow for fabrication of the package substrate cavity for an IPD may include a wafer level packaging (WLP) process technology. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an integrated circuit (IC) device. The terms “substrate,” “wafer,” and “laminate” may be used interchangeably. Similarly, the terms “chip” and “die” may be used interchangeably.

According to aspects of the present disclosure, an IC package having a package substrate cavity for an IPD is described. For example, the IC package includes a package die, such as an application processor die. The IC package also includes die interconnects on an active surface of the package die. In aspects of the present disclosure, the IC package provides a package cavity to accommodate an IPD. According to this aspect of the present disclosure, the package cavity enables accommodation of the IPD without increasing a Z-height of the IC package.

In one configuration, the IPD is contacted to an active surface of the package die, between the die interconnects. In this configuration, a portion of the IPD extends beyond a Z-height of the die interconnects. To accommodate the extended portion of the IPD without increasing a Z-height of the IC package, a package substrate includes a cavity to receive the extended portion of the IPD. The package substrate is attached to the package die through the die interconnects.

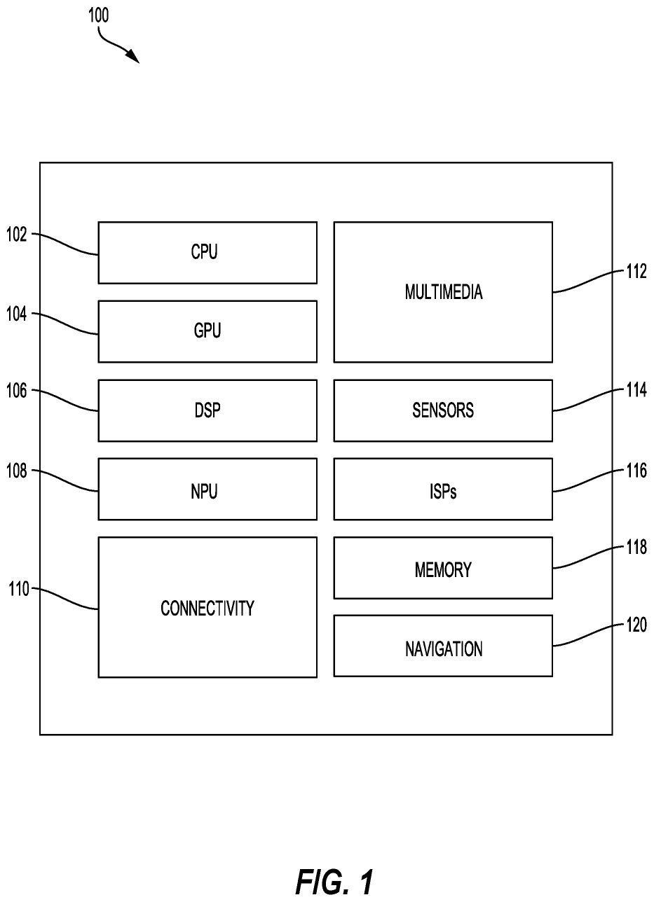

FIG. 1 illustrates an example implementation of a host system-on-a-chip (SoC) 100, which includes a package substrate cavity for an integrated passive device (IPD), in accordance with aspects of the present disclosure. The host SoC 100 includes processing blocks tailored to specific functions, such as a connectivity block 110. The connectivity block 110 may include fifth generation (5G) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, an advanced RISC machine (ARM), a microprocessor, or some other type of processor. The NPU 108 may be based on an ARM instruction set.

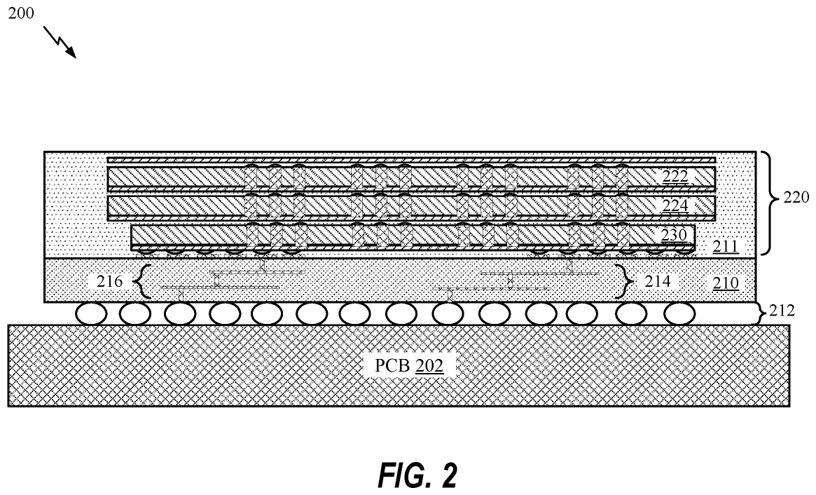

FIG. 2 shows a cross-sectional view illustrating a stacked integrated circuit (IC) package 200 of the SoC 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the SoC of FIG. 1.

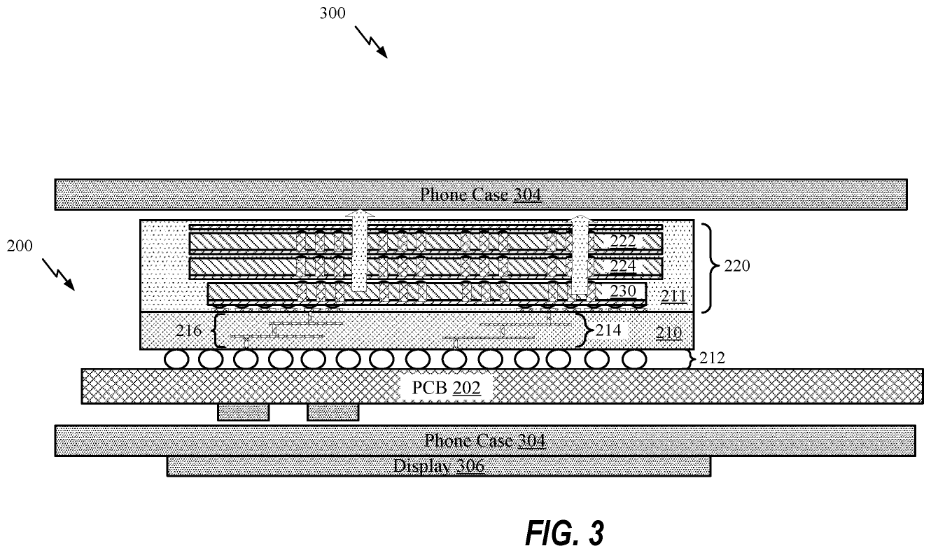

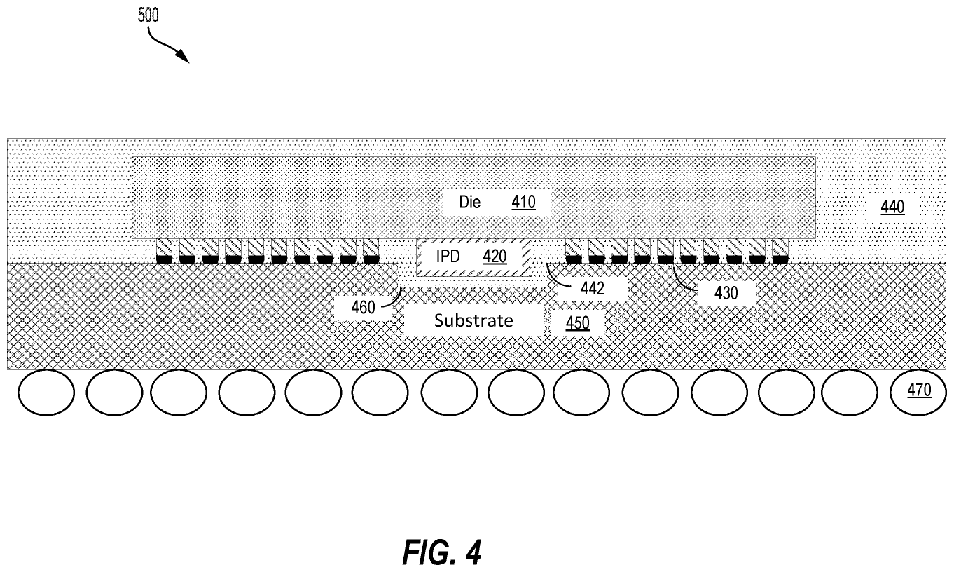

FIG. 3 shows a cross-sectional view illustrating the stacked IC package 200 of FIG. 2, incorporated into a wireless device 300, according to one aspect of the present disclosure. As described, the wireless device 300 may include, but is not limited to, a smartphone, tablet, handheld device, or other limited form factor device configured for 5G communications. Representatively, the stacked IC package 200 is arranged within a phone case 304, including a display 306. In this configuration, a package substrate cavity for an integrated passive device (IPD) is integrated into the stacked IC package 200, for example, as shown in FIG. 4.

FIG. 4 is cross-section of an integrated circuit (IC) package having a package substrate cavity for an integrated passive device (IPD), according to aspects of the present disclosure. An integrated circuit (IC) package 400 includes a package die 410, such as an application processor die configured for high performance computing. The IC package 400 also includes die interconnects 430 on an active surface 412 of the package die 410. In aspects of the present disclosure, the IC package 400 includes a package substrate cavity 460 (e.g., a package recess) to accommodate an IPD 420, such as inductors, capacitors, resistors, or other like passive device. According to this aspect of the present disclosure, the package substrate cavity 460 enables accommodation of the IPD 420 without increasing a Z-height of the IC package 400.

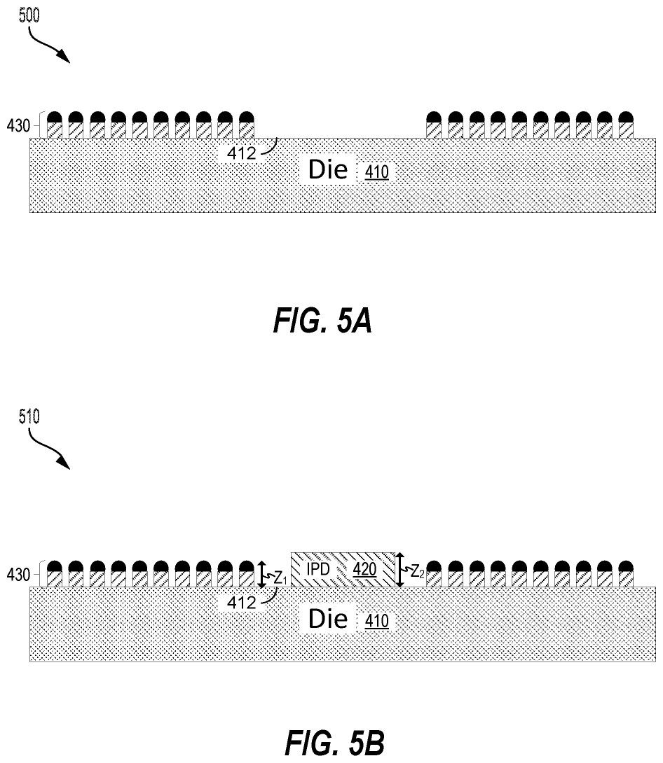

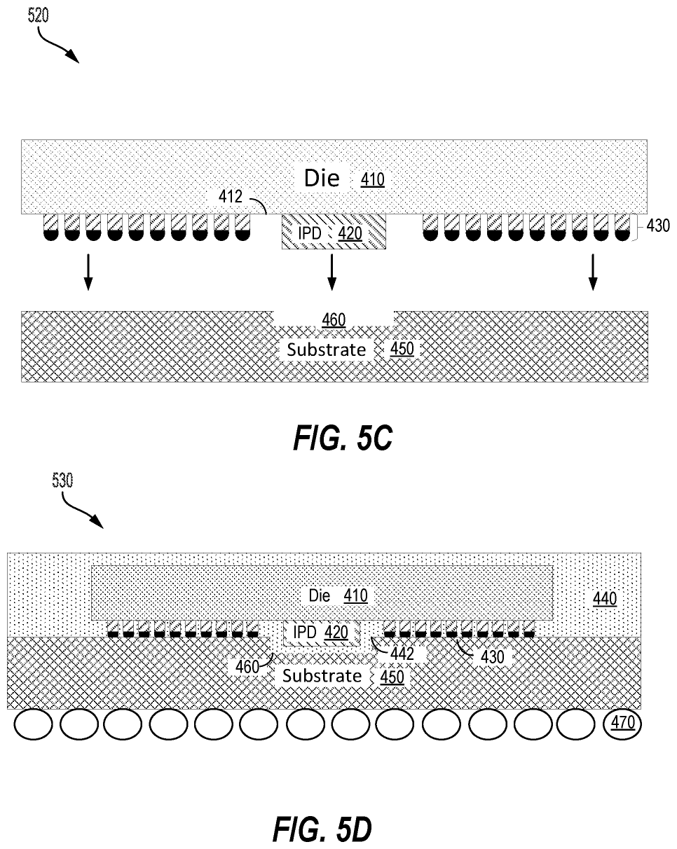

In one configuration, the IPD 420 is mounted on the active surface 412 of the package die 410, between the die interconnects 430. In this configuration, a portion of the IPD 420 extends beyond a Z-height of the die interconnects 430, as shown in FIG. 5B. To accommodate the extended portion of the IPD 420 without increasing a Z-height of the IC package, a package substrate 450 (e.g., a laminate substrate composed of a core and Ajinomoto build-up film (ABF) material (ABF substrate)) includes the package substrate cavity 460 to receive the extended portion of the IPD 420. Although described as an ABF substrate, aspects of the present disclosure contemplate configurations of the package substrate 450 using non-ABF material. The package substrate 450 is attached to the package die 410 through the die interconnects 430 and a mold compound 440. In addition, the package substrate 450 includes package bumps 470 (e.g., a ball grid array (BGA)).

As Moore's law slows with wafer technology advances, adding performance at the package level is desired to maintain continued capability trends. Aspects of the present disclosure add the IPD 420 in the IC package 400, which provides a desired increase in device performance (e.g., by 7%). One of the difficulties in realizing this benefit of the IPD 420 involves the connection of the IPD 420 to the package die 410.

According to aspects of the present disclosure, the IPD 420 is mounted to the active surface 412 of the package die 410. This mounting to the active surface 412 of the package die 410, however, creates a bonding issue between the package die 410 and the package substrate 450 due to a limitation against thinning (e.g., the Z-height) of the IPD 420. Aspects of the present disclosure solve this issue by forming a package substrate cavity 460 in the package substrate 450. The package substrate cavity 460 provides a recess for the IPD 420 sufficient for the adjacent die interconnects 430 to bond to the package substrate 450, which may be fabricated as shown in FIGS. 5A-5D.

FIGS. 5A-5D are cross-section diagrams illustrating a process of fabricating the IC package 400 having the package substrate cavity 460 for the IPD 420 of FIG. 4, according to aspects of the present disclosure. Although a single integrated passive device is shown in FIG. 4, it should be recognized that any number of IPDs may be used depending on the desired application, such as an application processor die.

As shown in FIG. 5A, at step 500, die interconnects 430 are formed on an active surface 412 of the package die 410. In alternative configurations, one of the die interconnects 430 may be a dummy die interconnect. In addition, a pitch of one of the die interconnects 430 (e.g., an outer die interconnect) is greater than at least another one of the die interconnects 430 (e.g., an inner die interconnect). As shown in FIG. 5B, at step 510, the IPD 420 is mounted on the active surface 412 of the package die 410. For example, a copper pad of the IPD 420 may be directly coupled to a copper pad of the package die 410 using a solder connection. Adding the IPD 420 in the IC package 400 provides a desired increase in device performance (e.g., by 7%) because the IPD 420 is directly mounted on the active surface 412 of the package die 410.

Although FIG. 5A shows mounting of the IPD 420 prior to formation of the die interconnects 430, in FIG. 5B, the order may be reversed. In this configuration, the IPD 420 is placed between the die interconnects 430. In this example, a portion of the IPD 420 extends beyond a Z₁-height (e.g. fifty (50) microns) of the die interconnects 430, which is less than a Z₂-height (e.g. one hundred twenty (120) microns) of the IPD 420. To accommodate the extended portion of the IPD 420 without increasing a Z-height of the IC package 400, a package substrate 450 includes the package substrate cavity 460 to receive the extended portion of the IPD 420, as shown in FIG. 5C.

As shown in FIG. 5C, at step 520, the package substrate cavity 460 is formed in the package substrate 450. For example, the package substrate 450 may be patterned and etched to expose a core of the package substrate 450 according to the desired dimensions (e.g., one-hundred (100) microns in depth) of the package substrate cavity 460. Forming the package substrate cavity 460 in the package substrate 450 (e.g., of an eight hundred (800) micron depth) provides a recess to receive the portion of the IPD 420 that extends beyond the Z₁-height of the die interconnects 430.

As shown in FIG. 5D, at step 530, the package substrate 450 is attached to the package die 410 through the die interconnects 430 after a reflow process of the die interconnects 430. In this example, the package substrate 450 is attached to the package die 410 through the die interconnects 430 and the mold compound 440. In addition, a mold underfill 442 is deposited between the IPD 420 and the package substrate cavity 460. The mold underfill 442 is also deposited between the die interconnects 430 and the IPD 420 to encapsulate the IPD 420. The mold underfill 442 may be composed of a die attach material (e.g., Henkel 8068TB V3), and the mold compound 440 may be composed of a different material, such as filled epoxy resin (e.g., Sumitomo G311Q-L). In alternative configuration, the mold underfill 442 may be replaced with a capillary underfill or a mixture of materials.

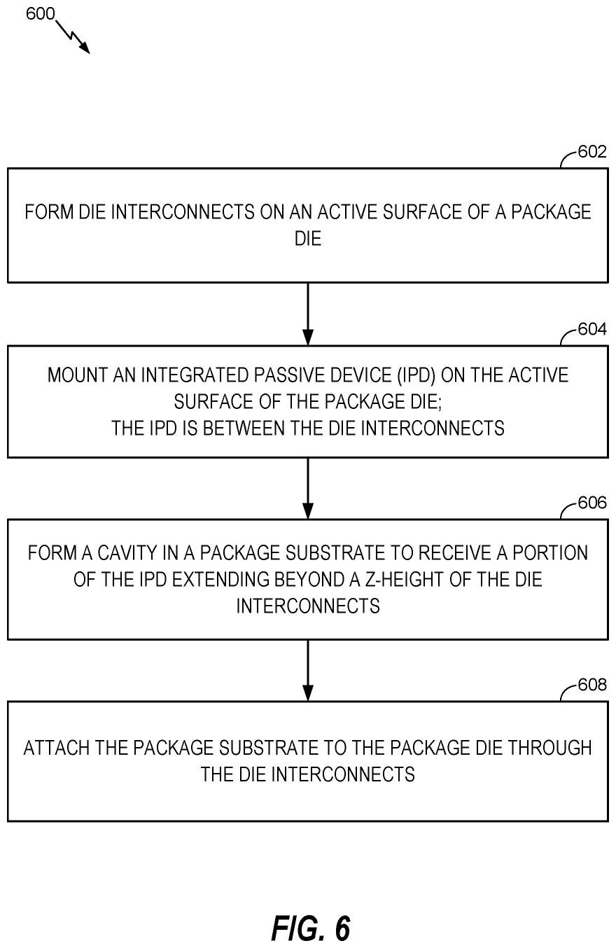

FIG. 6 is a process flow diagram illustrating a method for fabricating an integrated circuit (IC) package having a package substrate cavity for an integrated passive device (IPD), according to an aspect of the present disclosure. A method 600 begins at block 602, in which die interconnects are forming on the active surface of the package die. For example, as shown in FIG. 5A, the die interconnects 430 are formed on the active surface 412 of the package die 410. At block 604, an IPD is mounted on an active surface of a package die. The IPD is between the die interconnects. For example, as shown in FIG. 5B, the IPD 420 is mounted on the active surface 412 of the package die 410. In this example, the IPD 420 is placed between the die interconnects 430.

At block 606, a cavity is formed in a package substrate to receive a portion of the IPD extending beyond a Z-height of the die interconnects. For example, as shown in FIG. 5C, the package substrate cavity 460 is formed in the package substrate 450 using a pattern and etch process according to the desired dimensions of the package substrate cavity 460. Forming the package substrate cavity 460 in the package substrate 450 provides a recess to receive the portion of the IPD 420 that extends beyond the Z₁-height of the die interconnects 430. At block 608, the package substrate is attached to the package die through the die interconnects. For example, as shown in FIG. 5D, the package substrate 450 is attached to the package die 410 through the die interconnects 430 after a reflow process of the die interconnects 430. In this example, the package substrate 450 is attached to the package die 410 through the die interconnects 430 and the mold compound 440.

According to a further aspect of the present disclosure, an integrated circuit (IC) includes a package substrate cavity for an integrated passive device (IPD). In one configuration, the IC has means for means for filling between the IPD and the cavity of the package substrate and between die interconnects and the IPD. In one configuration, the filing means may be the mold under fill 442, as shown in FIG. 5D. In another aspect, the aforementioned means may be any structure or any material configured to perform the functions recited by the aforementioned means. (Completed after claim language approval).

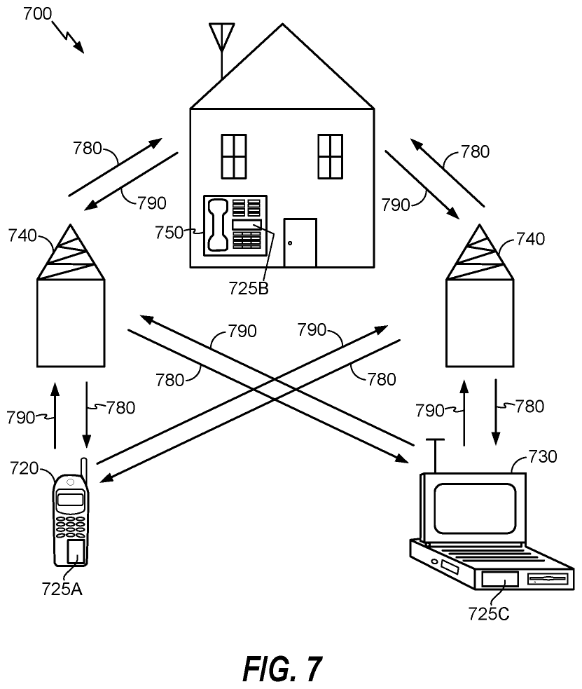

FIG. 7 is a block diagram showing an exemplary wireless communications system 700 in which an aspect of the present disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include IC devices 725A, 725B, and 725C that include the disclosed package substrate cavity for an IPD. It will be recognized that other devices may also include the disclosed package substrate cavity for an IPD, such as the base stations, switching devices, and network equipment. FIG. 7 shows forward link signals 780 from the base stations 740 to the remote units 720, 730, and 750, and reverse link signals 790 from the remote units 720, 730, and 750 to the base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof Although FIG. 7 illustrates remote units according to the aspects of the present disclosure, the disclosure is not limited to these exemplary illustrated units. Aspects of the present disclosure may be suitably employed in many devices, which include the disclosed package substrate cavity for an IPD.

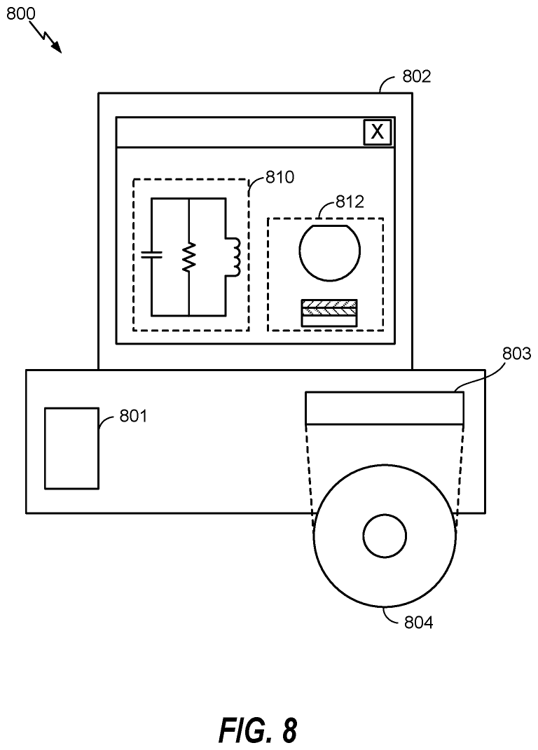

FIG. 8 is a block diagram illustrating a design workstation used for circuit, layout, and logic design of a semiconductor component, such as the capacitors disclosed above. A design workstation 800 includes a hard disk 801 containing operating system software, support files, and design software such as Cadence or OrCAD. The design workstation 800 also includes a display 802 to facilitate design of a circuit 810 or an integrated circuit (IC) component 812, such as a package substrate cavity for an integrated passive device (IPD). A storage medium 804 is provided for tangibly storing the design of the circuit 810 or the IC component (e.g., the package substrate cavity for an IPD). The design of the circuit 810 or the IC component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the IC component 812 by decreasing the number of processes for designing semiconductor wafers.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined may be applied to other variations without departing from the spirit or scope of the disclosure. Thus, the disclosure is not intended to be limited to the examples and designs described but is to be accorded the widest scope consistent with the principles and novel features disclosed.

What is claimed is:

1. An integrated circuit (IC) package, comprising:
a package die;
a plurality of die interconnects on an active surface of the package die;
an integrated passive device (IPD) coupled to the active surface of the package die, between the plurality of die interconnects, in which a portion of the IPD extends beyond a Z-height of the plurality of die interconnects; and
a package substrate coupled to the plurality of die interconnects, the package substrate comprising a cavity to receive the portion of the IPD.

2. The IC package of claim 1, further comprising:
a mold underfill between the IPD and the cavity of the package substrate.

3. The IC package of claim 2, further comprising the mold underfill between the plurality of die interconnects and the IPD.

4. The IC package of claim 1, in which the Z-height of the plurality of die interconnects is less than a Z-height of the IPD.

5. The IC package of claim 1, in which at least one of the plurality of die interconnects comprises a dummy die interconnect.

6. The IC package of claim 1, in which a pitch of at least one of the plurality of die interconnects is greater than at least another one of the plurality of die interconnects.

7. The IC package of claim 1, in which the plurality of die interconnects comprise copper pillar bumps.

8. The IC package of claim 1, further comprising a plurality of package bumps coupled to the package substrate.

9. The IC package of claim 1, in which the plurality of package bumps comprise a ball grid array (BGA).

10. A method for fabricating an integrated circuit package having a package substrate cavity for an integrated passive device (IPD), comprising:
forming a plurality of die interconnects on an active surface of a package die;
mounting the IPD on the active surface of the package die, in which the IPD is between the plurality of die interconnects;
forming the package substrate cavity in a package substrate to receive a portion of the IPD extending beyond a Z-height of the plurality of die interconnects; and
attaching the package substrate to the package die through the plurality of die interconnects.

11. The method of claim 10, further comprising depositing a mold underfill between the IPD and the cavity of the package substrate.

12. The method of claim 11, further comprising depositing the mold underfill between the plurality of die interconnects and the IPD.

13. The method of claim 10, further comprising disconnecting at least one of the plurality of die interconnects to provide a dummy die interconnect.

14. The method of claim 10, in which forming plurality of die interconnects comprises controlling a pitch of at least one of the plurality of die interconnects being greater than at least another one of the plurality of die interconnects.

15. The method of claim 10, in which attaching the package substrate comprises reflowing the plurality of die interconnects to couple the package substrate to the package die through the plurality of die interconnects.

16. The method of claim 10, further comprising forming a plurality of package bumps on the package substrate.

17. An integrated circuit (IC) package, comprising:
a package die;
a plurality of die interconnects on an active surface of the package die;
an integrated passive device (IPD) coupled to the active surface of the package die, between the plurality of die interconnects, in which a portion of the IPD extends beyond a Z-height of the plurality of die interconnects;
a package substrate coupled to the plurality of die interconnects, the package substrate comprising a cavity to receive the portion of the IPD; and
means for filling between the IPD and the cavity of the package substrate and between the plurality of die interconnects and the IPD.

18. The IC package of claim 17, in which the Z-height of the plurality of die interconnects is less than a Z-height of the IPD.

19. The IC package of claim 17, in which a pitch of at least one of the plurality of die interconnects is greater than at least another one of the plurality of die interconnects.

20. The IC package of claim 17, in which the plurality of die interconnects comprise copper pillar bumps.
